(19) United States
(12) Patent Application Publication
(10) Pub. No.: US 2024/0357873 A1
(43) Pub. Date: Oct. 24, 2024

(54) COMMON CO-PIXEL OLED DEVICE

(71) Applicant: Applied Materials, Inc., Santa Clara, CA (US)

(72) Inventors: Yu-Hsin LIN, Zhubei City (TW); Chung-Chia CHEN, Hsinchu City (TW); Takuji KATO, Yokohama City (JP); Ji Young CHOUNG, Hwaseong-si (KR)

(21) Appl. No.: 18/639,882

(22) Filed: Apr. 18, 2024

Related U.S. Application Data
(60) Provisional application No. 63/460,500, filed on Apr. 19, 2023.

(51) Int. Cl. H10K 59/122; H10K 59/173; H10K 59/80

(52) U.S. Cl. CPC H10K 59/122; H10K 59/173; H10K 59/80521

(57) ABSTRACT

Embodiments described herein relate to sub-pixel circuits and for a display such as an organic light-emitting diode (OLED) display. In one embodiment, a device is provided. The device includes a substrate, two external pixel-defining layer (PDL) structures disposed over the substrate, an overhang opening defined by a top extensions of top structures disposed on and extending laterally past body structures, each body structure disposed over an upper surface of each external PDL structure, the overhang openings defining at least two sub-pixels including a first sub-pixel and a second sub-pixel, and at least one internal PDL structure disposed over the substrate, wherein the first sub-pixel and the second sub-pixel are connected over a top surface of the internal PDL structure with a first organic light-emitting diode (OLED) material of the first sub-pixel connecting a second OLED material of the second sub-pixel on the top surface of the internal PDL structure.

### CROSS-REFERENCE TO RELATED APPLICATIONS

This application claims priority to U.S. Provisional Patent Application Ser. No. 63/460,500, filed on Apr. 19, 2023, which is herein incorporated by reference.

### BACKGROUND

### Field

Embodiments described herein generally relate to a display. More specifically, embodiments described herein relate to sub-pixel circuits and for a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

Encapsulation layers are used on OLED devices. During etching, residue can be left behind in the OLED device. This residue can cause dark points in the OLED device. Accordingly, what is needed in the art are sub-pixel circuits.

### SUMMARY

In one embodiment, a device is provided. The device includes a substrate, two external pixel-defining layer (PDL) structures disposed over the substrate, an overhang opening defined by a top extensions of top structures disposed on and extending laterally past body structures, each body structure disposed over an upper surface of each external PDL structure, the overhang opening defines at least two sub-pixels including a first sub-pixel and a second sub-pixel, and at least one internal PDL structure disposed over the substrate, wherein the first sub-pixel and the second sub-pixel are connected over a top surface of the internal PDL structure with a first organic light-emitting diode (OLED) material of the first sub-pixel connecting a second OLED material of the second sub-pixel on the top surface of the internal PDL structure.

In another embodiment, a device is provided. The device includes a substrate, a first and second pixel defining layers (PDLs) formed over the substrate defines at least two sub-pixels with a space therebetween, each of the first and second PDLs including a first and second overhang structure thereover, an anode formed over the substrate in each of the sub-pixel, an OLED material formed over the anode of each of the sub-pixels, and a cathode formed over the OLED material. The cathode extends under each of the overhang structures to contact both a first sidewall of the first overhang structure and a second sidewall of a second overhang structure, such that current may flow from the cathode to at least one of the first sidewall and the second sidewall during OLED emission.

In another embodiment, a device is provided. The device includes a substrate, external pixel-defining layer (PDL) structures disposed over the substrate and defining sub-pixels of the device, a plurality of overhang openings, each overhang opening defined by a plurality of top extensions of a plurality of top structures disposed on and extending laterally past a plurality of body structures, each body structure disposed over an upper surface of each external PDL structure, each overhang opening of the plurality of overhang openings defines at least two sub-pixels including a plurality of first sub-pixels and a plurality of second sub-pixels, and internal PDL structures disposed over the substrate and further defining the first sub-pixels and second sub-pixels of the device, wherein the first sub-pixels and the second sub-pixels are connected over a top surface of the internal PDL structures with a first organic light-emitting diode (OLED) material of the first sub-pixels connecting a second OLED material of the second sub-pixels on the top surface of the internal PDL structures. The first sub-pixels includes a first anode, the first OLED material disposed over the first anode, under the top extensions, and over a first portion of the top surface of the internal PDL structures, a first cathode in contact with a first sidewall of the body structures and disposed over the first OLED material and the first portion of the top surface of the internal PDL structures, and a first encapsulation layer disposed over the first cathode, the first sidewall of the body structures and the first portion of the top surface of the internal PDL structures. The second sub-pixels includes a second anode, the second OLED material disposed over the second anode, under the top extensions, and over a second portion of the top surface of the internal PDL structures, a second cathode in contact with a second sidewall of the body structures and disposed over the second OLED material and the second portion of the top surface of the internal PDL structures, and a second encapsulation layer disposed over the second cathode, the second sidewall of the body structures and the second portion of the top surface of the internal PDL structures. The first cathode connects to the second cathode over the top surface of the internal PDL structure.

In another embodiment, a sub-pixel circuit is provided. The sub-pixel circuit includes a substrate, external pixel-defining layer (PDL) structures disposed over the substrate and defining sub-pixels, internal PDL structure disposed over the substrate and defining sub-pixels, an overhang opening, the overhang opening defined by top extensions of top structures disposed on and extending laterally past body structures, the body structures disposed over an upper surface of the external PDL structures, the overhang opening defining at least two sub-pixels including a first sub-pixel and a second sub-pixel, the first sub-pixel and the second sub-pixel having the internal PDL structure therebetween. The first sub-pixel includes a first anode, a first organic light-emitting diode (OLED) material disposed over the first anode, under the top extensions, and over a first portion of a top surface of the internal PDL structure, a first cathode in contact with a first sidewall of the body structures and disposed over the first OLED material and the first portion of the top surface of the internal PDL structure, and a first encapsulation layer disposed over the first cathode, the first sidewall of the body structure and the first portion of the top surface of the internal PDL structure. The second sub-pixel includes a second anode, a second OLED material disposed over the second anode, under the top extensions, and over a second portion of the top surface of the internal PDL structure, a second cathode in contact with a second sidewall of the body structure, disposed over the second OLED material and the second portion of the top surface of the internal PDL structure, and a second encapsulation layer disposed over the second cathode, the second sidewall of the body structure and the second portion of the top surface of the internal PDL structure, wherein the first cathode connects to the second cathode over the top surface of the internal PDL structure and the first cathode and second cathode are in contact with both the first sidewall and second sidewall of the body structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a schematic, top sectional view of a sub-pixel circuit, according to embodiments.

FIG. 1B is a schematic, top sectional view of a sub-pixel circuit, according to embodiments.

FIG. 1C is a schematic, cross-sectional view of a sub-pixel circuit, according to embodiments.

FIG. 1D is a schematic, cross-sectional view of a sub-pixel circuit, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display.

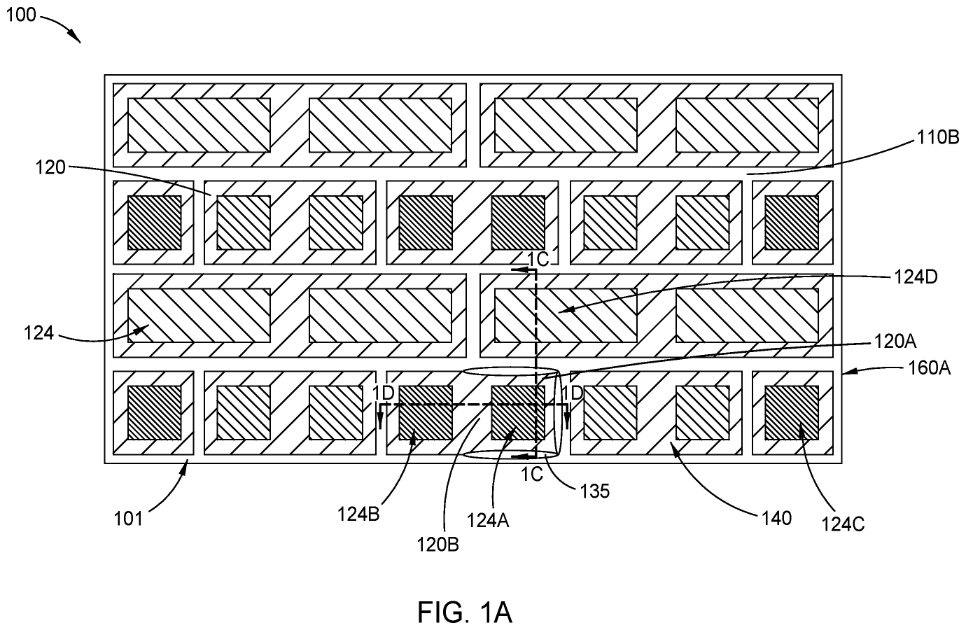

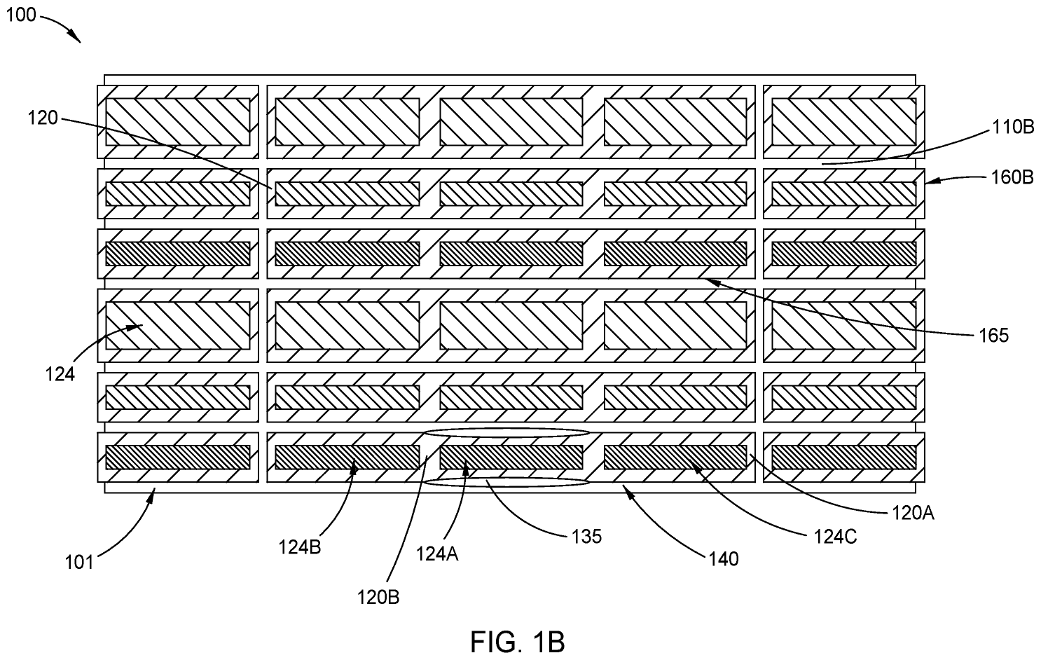

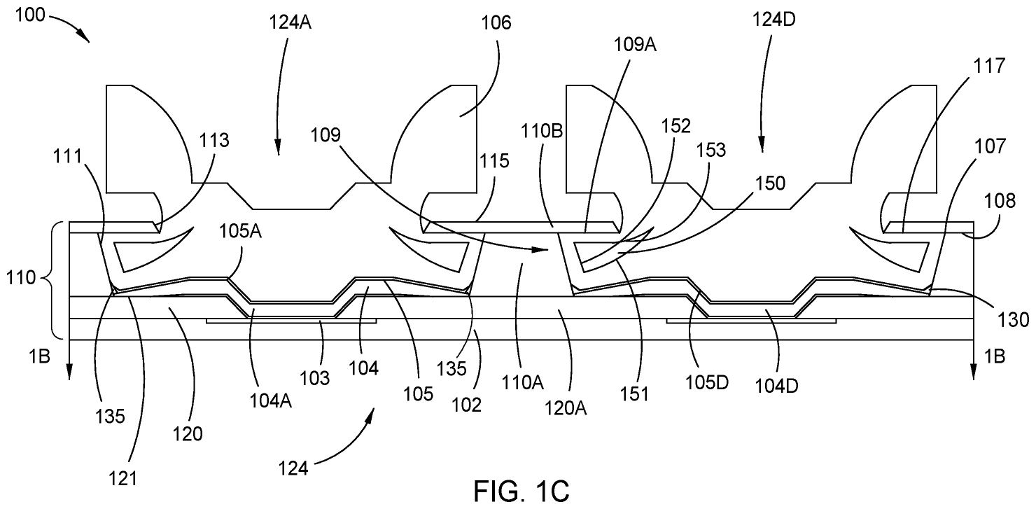

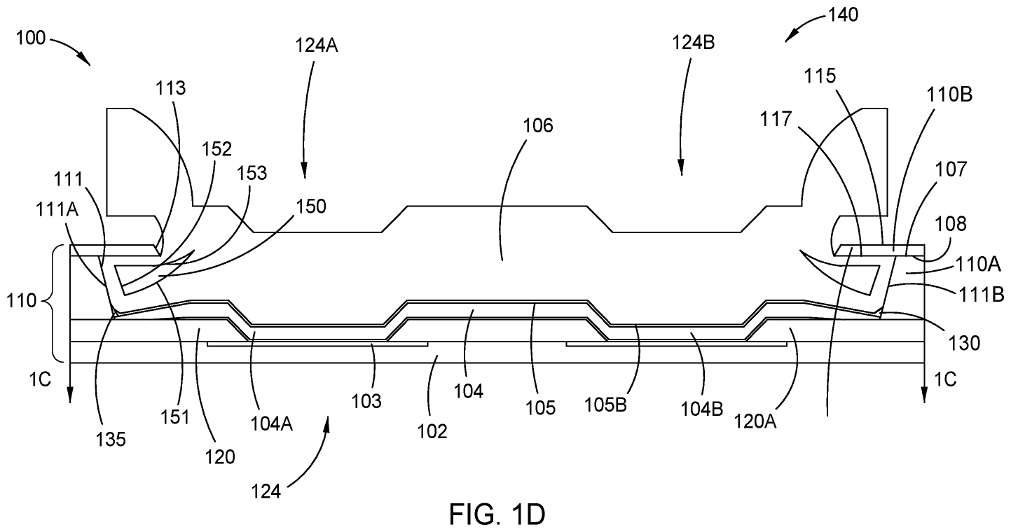

FIG. 1A is a schematic, top sectional view of a sub-pixel circuit 100. The sub-pixel circuit 100 of FIG. 1A has a semi line-type architecture 101 of a first formation 160A. The semi line-type architecture 101 combines sub-pixel grouping with local contact architecture. Local contact architecture has the direct contact of each sub-pixel 124 with overhang structures 110 that form the overhang openings 140. The direct contact allows the voltage across sub-pixels 124 to not drop. In dot-type architecture, each individual sub-pixel 124 is defined by a single overhang opening 140 and has local contact, i.e. direct contact to the overhang structures 110. In line-type architecture, a whole row or a column of sub-pixels 124 is defined by the single overhang opening 140. The semi line-type architecture 101 has at least two sub-pixels 124 in each of the overhang openings 140. In some embodiments, each pixel on a device has a semi line-type architecture 101 as shown in the sub-pixel circuit 100. In other embodiments, the device has some pixels in the semi line-type architecture 101 and some are in dot-type architecture. A pixel in in dot-type architecture will have a single sub-pixel 124 in the overhang openings 140. The first formation 160A has a first sub-pixel 124A and a second sub-pixel 124B defined by the single overhang opening 140. The overhang openings 140 are defined by a plurality of top structures 110B described in FIGS. 1C and 1D. The first sub-pixel 124A and second sub-pixel 124B are defined by a pixel defining layer (PDL) structure 120. The PDL structures 120 that border the top structures 110B are external PDL structures 120A. The PDL structures 120 that separate two sub-pixels in the single overhang opening 140, e.g. the first sub-pixel 124A and the second sub-pixel 124B, are internal PDL structures 120B, as shown in FIG. 1D. The internal PDL structures 120B are disposed in a space therebetween at least two sub-pixels, such as the first sub-pixel 124A and the second sub-pixel 124B.

A residue 135 as shown in FIG. 1A may be left behind on sidewalls of overhang structures 110. The residue 135 may be generated during a pattering process of prior formed pixels. For example, after depositing an OLED material 104 or an encapsulation layer 106 on the first sub-pixel 124A after formation of the second sub-pixel 124B, or removal of the OLED material 104 or the encapsulation layer 106 from the first sub-pixel 124. These prior processes may cause the residue 135 at latter sub-pixels 124, such as the first sub-pixel 124A after formation of the second sub-pixel 124B. The residue 135 can interfere with the sub-pixel 124 performance. The residue 135 can interfere with a cathode connection 130 with the sidewalls as shown in FIGS. 1C and 1D. The residue 135 can weaken or block the cathode connection 130. The residue 135 is further described in FIG. 1C. In dot type architecture, the residue 135 will cause the sub-pixel 124 to malfunction causing a dark point. With the semi-line type architecture, the cathode connection 130 in the second sub-pixel 124B provides a connection to the first sub-pixel 124A. The connection removes the dark point and maintains local contact. The residue 135 may exist in only some instances, and only on some of the sidewalls. The residue 135 is not necessary to implement the sub-pixel circuit 100 described herein. Current may flow from the anode to the OLED materials 104, and from the cathode 105 to at least one of the first sidewall 111A and the second sidewall 111B of the overhang structures 110 during OLED emission, and in some embodiments, to both the first sidewall 111A and the second sidewall 111B during OLED emission. The overhang structures 110 may provide electrical communication with at least one bus bar to complete the electrical connection.

FIG. 1B is a schematic, top sectional view of the sub-pixel circuit 100. The sub-pixel circuit 100 of FIG. 1B has the semi line-type architecture 101 of a second formation 160B. The second formation 160B includes at least three rows 165. Each row 165 includes at least two sub-pixels 124. The sub-pixels 124 of each row 165 are configured to emit the same color light. At least two rows 165 are configured to display a different color light. The second formation 160B has at least two sub-pixels 124 in each overhang opening 140. As shown in FIG. 1B, he second formation 160B may have the first sub-pixel 124A, the second sub-pixel 124B and a third sub-pixel 124C defined by the single overhang opening 140. The overhang openings 140 are defined by the plurality of top structures 110B. The first sub-pixel 124A, the second sub-pixel 124B, and the third sub-pixel 124C are defined by the PDL structures 120. The PDL structures 120 that border the top structures 110B are external PDL structures 120A. The PDL structures 120 that separate the first sub-pixel 124A, the second sub-pixel 124B, and the third sub-pixel 124C are internal PDL structures 120B. In some embodiments, a different formation may be used and the single overhang opening 140 defines at least two sub-pixels 124.

FIG. 1C is a schematic, cross-sectional view of the sub-pixel circuit 100 across section line 1C-1C. FIG. 1C shows the first sub-pixel 124A and a fourth sub-pixel 124D from adjacent overhang openings 140. The first sub-pixel 124A has residue 135 while the fourth sub-pixel 124D does not have residue 135. The residue 135 may exist in only some instances, and only on some of the sidewalls. The residue 135 is not necessary to implement the sub-pixel circuit 100 described herein. Current may flow from the anode to the OLED materials 104, and from the cathode 105 to at least one of the first sidewall 111A and the second sidewall 111B of the overhang structures 110 during OLED emission, and in some, embodiments to both the first sidewall 111A and the second sidewall 111B during OLED emission. The overhang structures 110 may provide electrical communication with at least one bus bar to complete the electrical connection. Current flows from at least one of the first sidewall 111A and the second sidewall 111B to the bus bar during OLED emission.

The sub-pixel circuit 100 includes a substrate 102. Metal containing layers 103 are disposed over the substrate 102. The metal containing layers 103 are defined by the adjacent PDL structures 120 disposed over the substrate 102. In some embodiments, the metal containing layers 103 are pre-patterned on the substrate 102 and the substrate is a pre-patterned indium tin oxide (ITO) glass substrate. The metal containing layers 103 are configured to operate as anodes of respective sub-pixels 124. The metal containing layers 103 include, but are not limited to, chromium, titanium, gold, silver, copper, aluminum, ITO, a combination thereof or other suitably conductive materials. In some embodiments, the metal containing layers 103 are a stack including an ITO layer disposed on a silver layer disposed on an ITO layer.

The PDL structures 120 are disposed over the substrate 102. The PDL structures 120 include one of an organic material, an organic material with an inorganic coating disposed thereover, or an inorganic material. The organic material of the PDL structures 120 includes, but is not limited to, polyimides. Inorganic material of the PDL structures 120 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures 120 define the respective sub-pixels 124 of the sub-pixel circuit 100. Internal PDL structures 120B define the respective sub-pixels 124 inside a single overhang opening 140. External PDL structures 120A define the sub-pixels 124 with respect to sub-pixels 124 in adjacent overhang openings 140.

Each sub-pixel 124 has an organic light-emitting diode (OLED) material 104 configured to emit a white, red, green, blue or other color light when energized. Sub-pixels 124 in the same overhang opening 140 have the same OLED material. In some embodiments as shown in FIG. 1C, the first sub-pixel 124A has a first OLED material 104A configured to emit red light. The fourth sub-pixel 124D has a fourth OLED material 104D configured to emit blue light.

Overhang structures 110 are disposed over an upper surface 121 of external PDL structures 120A. The overhang structures 110 are permanent to the sub-pixel circuit. The overhang structure 110 further define sub-pixels 124 of the sub-pixel circuit 100 via the overhang openings 140. The overhang structures 110 includes at least a top structure 110B disposed over a body structure 110A. In one embodiment, the top structure 110B is disposed on the body structure 110A. The body structure 110A is disposed over the upper surface 121 of the PDL structure 120. In one embodiment, the body structure 110A is disposed on the upper surface 121 of the PDL structure 120. Each overhang structure 110 includes adjacent overhangs 109. The adjacent overhangs 109 are defined by a top extension 109A of the top structure 110B extending laterally past a sidewall 111 of the body structure 110A.

The top structure 110B includes one of a non-conductive material, inorganic material, or metal-containing material. The body structure 110A includes an inorganic material or a metal-containing material. The non-conductive material includes, but is not limited to, an inorganic silicon-containing material. E.g., the silicon-containing material includes oxides or nitrides of silicon, or combinations thereof. The metal-containing materials include at least one of a metal or metal alloy such as titanium (Ti), aluminum (AI), aluminum neodymium (AlNd), molybdenum (Mo), molybdenum tungsten (MoW), copper (Cu), or combinations thereof. The inorganic materials of the body structure 110A and the top structure 110B include silicon nitride (Si₃N₄), silicon oxide (SiO₂), silicon oxynitride (Si₂N₂O), amorphous silicon or combinations thereof.

In one embodiment, the top structure 110B includes a non-conductive inorganic material and the body structure 110A includes a conductive inorganic material or a metal-containing material. In another embodiment, the top structure 110B includes a conductive inorganic material or metal-containing material and the body structure 110A includes a conductive inorganic material or metal-containing material.

Adjacent overhangs 109 are defined by the top extension 109A of the top structure 110B. At least a bottom surface 107 of the top structure 110B is wider than a top surface 108 of the body structure 110A to form the top extension 109A of the overhang 109. The top structure 110B is disposed over a top surface 108 of the body structure 110A. The top extension 109A of the top structure 110B forms the overhang 109 and allows for the top structure 110B to shadow the body structure 110A.

The OLED material 104 is disposed under the overhang 109 on the metal containing layer 103 and the PDL structures 120. A cathode 105 is disposed over the OLED material 104 and extends under the overhang 109. The cathode 105 contacts the sidewall 111 of the body structure 110A to create the cathode connection 130. Current flows from the cathode 105 to the sidewall 111. The cathode connection 130 causes the sub-pixel 124 to emit light when activated. Weakening the cathode connection 130 causes less light to be emitted by the sub-pixel 124. The sub-pixel 124 cannot be activated when the cathode connection 130 is blocked. The first sub-pixel 124A has a first cathode 105A. The fourth sub-pixel 124D has a fourth cathode 105D. The cathode 105 includes a conductive material, such as a metal or metal alloy. E.g., the cathode 105 includes, but is not limited to, silver, magnesium, chromium, titanium, aluminum, ITO, or a combination thereof. In some embodiments, the material of the cathode 105 is different from the material of the body structure 110A and the top structure 110B.

Each sub-pixel 124 includes an encapsulation layer 106. The encapsulation layer 106 may be or may correspond to a local passivation layer. The encapsulation layer 106 of a respective sub-pixel 124 is disposed over the cathode 105 (and OLED material 104) with the encapsulation layer 106 extending under at least a portion of the overhang structures 110 and over at least a portion of a sidewall 111 of each of the adjacent overhang structures 110. In one embodiment, the encapsulation layer 106 is disposed over the sidewall 111 of the body structure 110A, the bottom surface 107 of the top structure 110B, a sidewall 113 of the top structure 110B, and a portion of a top surface 115 of the top structure 110B of the overhang structures 110. In one embodiment, the encapsulation layer 106 has gaps 150. Each of the gaps 150 is defined by a first portion 151, a second portion 152, a third portion 153, and the first portion 151 contacting the third portion 153 of the encapsulation layer 106. The first portion 151 of the encapsulation layer 106 is disposed over the cathode 105. The second portion 152 of the encapsulation layer 106 is disposed over the sidewall 111 of the body structure 110A. The third portion 153 of the encapsulation layer 106 is disposed under an underside surface 117 of the top extension 109A of the top structure 110B. The first portion 151 of the encapsulation layer 106 may contact the third portion 153 of the encapsulation layer 106.

The residue 135 may be formed from previous patterning of other OLED materials 104 and encapsulation layers 106. In some embodiments, other processes may cause the residue 135 to form in sub-pixels 124. In some sub-pixels 124, as shown in the first sub-pixel 124A, the residue 135 interferes with the cathode connection 130. The residue 135 is between the first cathode 105A and the sidewall 111 of the body structure 110A. The cathode connection 130 allows the sub-pixel 124 to activate. When the cathode connection 130 is blocked by the residue 135, the sub-pixel 124 cannot activate. The sub-pixel 124 not activating causes the dark point if every cathode connection 130 is blocked by the residue 135 in the sub-pixel 124. The residue 135 may exist in only some instances, and only on some of the sidewalls. The residue 135 is not necessary to implement the sub-pixel circuit 100 described herein. Current may flow from the anode to the OLED materials 104, and from the cathode 105 to at least one of the first sidewall 111A and the second sidewall 111B of the overhang structures 110 during OLED emission, and in some, embodiments to both the first sidewall 111A and the second sidewall 111B during OLED emission. The overhang structures 110 may provide electrical communication with at least one bus bar to complete the electrical connection. Current flows from at least one of the first sidewall 111A and the second sidewall 111B to the bus bar during OLED emission.

The fourth sub-pixel 124D does not have residue 135. With no residue 135, the cathode connections 130 are able to function properly. The fourth cathode 105D connects to the sidewall 111 of the body structure 110A. No dark point exists in the fourth sub-pixel 124D. The residue 135 may exist in only some instances, and only on some of the sidewalls. The residue 135 is not necessary to implement the sub-pixel circuit 100 described herein. Current may flow from the anode to the OLED materials 104, and from the cathode 105 to at least one of the first sidewall 111A and the second sidewall 111B of the overhang structures 110 during OLED emission, and in some, embodiments to both the first sidewall 111A and the second sidewall 111B during OLED emission.

FIG. 1D is a schematic, cross-sectional view of a sub-pixel circuit 100 across section line 1D-1D. FIG. 1D shows the first sub-pixel 124A and the second sub-pixel 124B from the single overhang opening 140. The first OLED material 104A of the first sub-pixel and a second OLED material 104B of the second sub-pixel 124B are the same. In FIG. 1D, the first OLED material 104A and the second OLED material 104B are configured to emit a red light when energized. In other embodiments, the first OLED material 104A and the second OLED material 104B are configured to emit a white, green, blue or other color light when energized. The first sub-pixel 124A has the residue 135 while the second sub-pixel 124B does not have the residue 135. As shown in FIG. 1C with the first sub-pixel 124A, the second sub-pixel 124B has the substrate 102, the metal containing layer 103, the OLED material 104, the cathode 105, and the encapsulation layer 106. In some embodiments, the cathode 105 includes the first cathode 105A of the first sub-pixel 124A and a second cathode 105B of the second sub-pixel 124B. The first cathode 105A connects to the second cathode 105B over a top surface of the internal PDL structures 120B. In other embodiments, the cathode 105 may be a continuous layer. The cathode 105 extends from the first sidewall 111A through the first sub-pixel 124A over the top surface of the internal PDL structure 120B. The cathode 105 then extends to the second sidewall 111B through the second sub-pixel 124B.

According to the semi line-type architecture 101, the second sub-pixel 124B is defined by the overhang structure 110 and the external PDL structures 120A on one side. On the other side, the second sub-pixel 124B is separated from the first sub-pixel 124A by the internal PDL structure 120B. The first OLED material 104A of the first sub-pixel 124A is connected to the second OLED material 104B of the second sub-pixel 124B. The first cathode 105A of the first sub-pixel 124A is connected to the second cathode 105B of the second sub-pixel 124B over the top surface of the internal PDL structure 120B. The connection of the first cathode 105A and the second cathode 105B allows the first cathode 105A to be connected to a second sidewall 111B of the body structure 110A of the second sub-pixel 124B via the second cathode 105B. The connection also allows the second cathode 105B to be connected to a first sidewall 111A of the body structure 110A of the first sub-pixel 124A via the first cathode 105A. If the cathode connection 130 is blocked at the first sidewall 111A, current flows from the first cathode 105A to the second sidewall 111B via the second cathode 105B during OLED emission. The first sub-pixel 124A will be activated even though the cathode connection 130 is being blocked at the first sidewall 111A. If the cathode connection 130 is blocked at the second sidewall 111B, current flows from the second cathode 105B to the first sidewall 111A via the first cathode 105A during OLED emission. The second sub-pixel 124B will be activated even though the cathode connection 130 is being blocked at the second sidewall 111B.

As shown in FIG. 1D, the first sub-pixel 124A has residue 135 blocking the cathode connection 130. As described in FIG. 1C, if the cathode connection 130 is blocked, the sub-pixel 124 cannot activate. The first sub-pixel 124A is able to activate with the cathode connection 130 at the second sidewall 111B of the body structure 110A of the second sub-pixel 124B. The first cathode 105A connects to the second cathode 105B over top of the internal PDL structure 120B. The second cathode 105B connects to the second sidewall 111B of the body structure 110A of the second sub-pixel 124B. Similarly if the cathode connection 130 of the first sub-pixel 124A is weakened at the first sidewall 111A of the body structure 110A of the first sub-pixel 124A, the cathode connection 130 at the second sidewall 111B of the body structure 110A of the second sub-pixel 124B can strengthen the cathode connection 130 of the first sub-pixel 124A.

In summation, embodiments described herein relate to the sub-pixel circuit 100 that may be utilized in a display such as OLED display. The sub-pixel circuit 100 has the semi line-type architecture 101. The semi line-type architecture 101 combines sub-pixel grouping with local contact architecture. The semi line-type architecture 101 has at least two sub-pixels 124, e.g. a first sub-pixel 124A and a second sub-pixel 124B, in each of the overhang openings 140. By having two sub-pixels 124 in a single overhang opening 140, one sub-pixel 124 with residue 135 can be activated by the cathode 105 of the paired sub-pixel 124. This will prevent dark points while retaining the benefit of local contact from dot-type architecture. The local contact architecture allows current to be driven from the cathode 105 per each sub-pixel 124. Since each cathode 105 connects to the body structure 110A, there is no voltage loss across sub-pixels 124 allowing for better device performance. The residue 135 may exist in only some instances, and only on some of the sidewalls. The residue 135 is not necessary to implement the sub-pixel circuit 100 described herein. Current may flow from the anode to the OLED materials 104, and from the cathode 105 to at least one of the first sidewall 111A and the second sidewall 111B of the overhang structures 110 during OLED emission, and in some, embodiments to both the first sidewall 111A and the second sidewall 111B during OLED emission. If the cathode connection 130 is blocked at the first sidewall 111A, current flows from the first cathode 105A to the second sidewall 111B via the second cathode 105B during OLED emission. The first sub-pixel 124A will be activated even though the cathode connection 130 is blocked at the first sidewall 111A. If the cathode connection 130 is blocked at the second sidewall 111B, current flows from the second cathode 105B to the first sidewall 111A via the first cathode 105A during OLED emission. The second sub-pixel 124B will be activated even though the cathode connection 130 is blocked at the second sidewall 111B. The overhang structures 110 may provide electrical communication with at least one bus bar to complete the electrical connection. Current flows from at least one of the first sidewall 111A and the second sidewall 111B to the bus bar during OLED emission.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate;
two external pixel-defining layer (PDL) structures disposed over the substrate;
an overhang opening defined by top extensions of top structures disposed on and extending laterally past body structures, each body structure disposed over an upper surface of each external PDL structure, the overhang opening defines at least two sub-pixels including a first sub-pixel and a second sub-pixel; and
at least one internal PDL structure disposed over the substrate, wherein the first sub-pixel and the second sub-pixel are connected over a top surface of the internal PDL structure with a first organic light-emitting diode (OLED) material of the first sub-pixel connecting a second OLED material of the second sub-pixel on the top surface of the internal PDL structure.

2. The device of claim 1, wherein a cathode is disposed on the first OLED material and the second OLED material, the cathode contacting a first sidewall of a first body structure and a second sidewall of a second body structure.

3. The device of claim 1, wherein the first sub-pixel comprising:
a first anode;
the first OLED material disposed over the first anode, under the top extensions, and over a first portion of the top surface of the internal PDL structure;
a first cathode in contact with a first sidewall of the body structures and disposed over the first OLED material and the first portion the top surface of the internal PDL structure; and
a first encapsulation layer disposed over the first cathode, the first sidewall of the body structures and the first portion of the top surface of the internal PDL structure.

4. The device of claim 3, wherein the second sub-pixel comprising:
a second anode;
the second OLED material disposed over the second anode, under the top extensions, and over a second portion the top surface of the internal PDL structures;
a second cathode in contact with a second sidewall of the body structures and disposed over the second OLED material and the second portion of the top surface of the internal PDL structures; and
a second encapsulation layer disposed over the second cathode, the second sidewall of the body structures and over the second portion of the top surface of the internal PDL structures.

5. The device of claim 4, wherein the first cathode connects to the second cathode over the top surface of the internal PDL structures.

6. The device of claim 5, wherein current flows from the first cathode to the second sidewall via the second cathode during OLED emission.

7. The device of claim 5, wherein current flows from the second cathode to the first sidewall via the first cathode during OLED emission.

8. A device comprising
a substrate;
a first and second pixel defining layers (PDLs) formed over the substrate defines at least two sub-pixels with a space therebetween;
each of the first and second PDLs including a first and second overhang structure thereover;
an anode formed over the substrate in each sub-pixel;
an OLED material formed over the anode of each of the sub-pixels; and
a cathode formed over the OLED material, wherein the cathode extends under each of the first overhang structures and the second overhang structure to contact both a first sidewall of the first overhang structure and a second sidewall of the second overhang structure, such that a current flows from the cathode to at least one of the first sidewall and the second sidewall during OLED emission.

9. The device of claim 8, wherein the current flows from at least one of the first sidewall and the second sidewall to a bus bar during OLED emission.

10. The device of claim 8, wherein the cathode includes a first cathode of a first sub-pixel and a second cathode of a second sub-pixel.

11. The device of claim 10, wherein the first cathode connects to the second cathode over a top surface of an internal PDL structure disposed in the space therebetween the two sub-pixels.

12. The device of claim 11, wherein current flows from the first cathode to the second sidewall via the second cathode during OLED emission.

13. The device of claim 11, wherein current flows from the second cathode to the first sidewall via the first cathode during OLED emission.

14. A device, comprising:
a substrate;
external pixel-defining layer (PDL) structures disposed over the substrate and defining sub-pixels of the device;
a plurality of overhang openings, each overhang opening defined by a plurality of top extensions of a plurality of top structures disposed on and extending laterally past a plurality of body structures, each body structure disposed over an upper surface of each external PDL structure, each overhang opening of the plurality of overhang openings defines at least two sub-pixels including a plurality of first sub-pixels and a plurality of second sub-pixels;
internal PDL structures disposed over the substrate and further defining the first sub-pixels and second sub-pixels of the device, wherein the first sub-pixels and the second sub-pixels are connected over a top surface of the internal PDL structures with a first organic light-emitting diode (OLED) material of the first sub-pixels connecting a second OLED material of the second sub-pixels on the top surface of the internal PDL structures;
the first sub-pixels comprising:
a first anode;
the first OLED material disposed over the first anode, under the top extensions, and over a first portion of the top surface of the internal PDL structures;
a first cathode in contact with a first sidewall of the body structures and disposed over the first OLED material and the first portion of the top surface of the internal PDL structures; and
a first encapsulation layer disposed over the first cathode, the first sidewall of the body structures and the first portion of the top surface of the internal PDL structures;
the second sub-pixels comprises:
a second anode;
the second OLED material disposed over the second anode, under the top extensions, and over a second portion of the top surface of the internal PDL structures;
a second cathode in contact with a second sidewall of the body structures and disposed over the second OLED material and the second portion of the top surface of the internal PDL structures; and
a second encapsulation layer disposed over the second cathode, the second sidewall of the body structures and the second portion of the top surface of the internal PDL structures; and
the first cathode connects to the second cathode over the top surface of the internal PDL structure.

15. The device of claim 14, wherein the first cathode connects to the second sidewall through the second cathode and the second cathode connects to the first sidewall through the first cathode.

16. The device of claim 15, wherein current flows from the first cathode to the second sidewall via the second cathode during OLED emission.

17. The device of claim 15, wherein current flows from the second cathode to the first sidewall via the first cathode during OLED emission.

18. A sub-pixel circuit, comprising:
a substrate;
external pixel-defining layer (PDL) structures disposed over the substrate and defining sub-pixels;
internal PDL structure disposed over the substrate and defining sub-pixels;
an overhang opening, the overhang opening defined by top extensions of top structures disposed on and extending laterally past body structures, the body structures disposed over an upper surface of the external PDL structures, the overhang opening defining at least two sub-pixels including a first sub-pixel and a second sub-pixel, the first sub-pixel and the second sub-pixel having the internal PDL structure therebetween;
the first sub-pixel comprising:
a first anode;
a first organic light-emitting diode (OLED) material disposed over the first anode, under the top extensions, and over a first portion of a top surface of the internal PDL structure;
a first cathode in contact with a first sidewall of the body structures and disposed over the first OLED material and the first portion of the top surface of the internal PDL structure; and
a first encapsulation layer disposed over the first cathode, the first sidewall of the body structure and the first portion of the top surface of the internal PDL structure;
the second sub-pixel comprising:
a second anode;
a second OLED material disposed over the second anode, under the top extensions, and over a second portion of the top surface of the internal PDL structure;
a second cathode in contact with a second sidewall of the body structure, disposed over the second OLED material and the second portion of the top surface of the internal PDL structure; and
a second encapsulation layer disposed over the second cathode, the second sidewall of the body structure and the second portion of the top surface of the internal PDL structure, wherein the first cathode connects to the second cathode over the top surface of the internal PDL structure and the first cathode and second cathode are in contact with both the first sidewall and second sidewall of the body structures.

19. The sub-pixel circuit of claim 18, wherein current flows from the first cathode to the second sidewall via the second cathode during OLED emission.

20. The sub-pixel circuit of claim 18, wherein current flows from the second cathode to the first sidewall via the first cathode during OLED emission.
